(19) United States
(12) Patent Application Publication
(10) Pub. No.: US 2008/0311965 A1
(43) Pub. Date: Dec. 18, 2008

(54) RADIATION-PROTECTIVE ENCLOSURE OF CELLULAR PHONE

(75) Inventors: FEI GAO, Shenzhen City (CN); WEN-HAW TSENG, Tu-Cheng (TW); SHIH-FANG WONG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/137,515

(22) Filed: Jun. 11, 2008

(30) Foreign Application Priority Data
Jun. 14, 2007 (CN) 200710200821.X

(51) Int. Cl. H05K 9/00; H04M 1/00

(52) U.S. Cl. 455/575.1

(57) ABSTRACT

A radio frequency (RF) radiation-protective enclosure for a cellular phone is disclosed. The RF radiation-protective enclosure includes a substrate and a reflection layer. The substrate includes an inner surface. The reflection layer is formed on the inner surface of the substrate. The surface of the reflection layer is formed with micro-protrusions. The micro-protrusions are configured for diffusely reflecting RF radiation emitted by the cellular phone, thus reducing reflected RF radiation from interfering with RF circuits of the cellular phone.

### BACKGROUND

1. Technical Field

The present invention relates to enclosures of cellular phones, and particularly to a radiation-protective enclosure of a cellular phone.

2. General Background

Cellular phone generates radio frequency (RF) radiation which may be harmful to people. Radiation-protective enclosure for cellular phone has been adopted to protect people from the RF radiation. The radiation-protective enclosure reflects or confines the RF radiation emitted within the cellular phone. However, the reflected or confined RF radiation may interfere with RF circuitry (RF circuits) within the cellular phone and thereby affecting the communication functionality of the cellular phone.

Thus, what is needed is an enclosure which reduces the reflection of RF radiation of a radiation-shielding enclosure of cellular phones.

### SUMMARY

A kind of radiation-protective enclosure for a cellular phone is disclosed. The radiation-protective enclosure includes a substrate and a reflection layer. The substrate includes an inner surface. The reflection layer is formed on the inner surface of the substrate. A surface of the reflection layer is formed with a plurality of micro-protrusions.

Further features and advantages will be provided or will become apparent in the course of the following detailed description.

### BRIEF DESCRIPTION OF THE DRAWINGS

The components of the drawings are not necessarily drawn to measuring scale, the emphasis instead being placed upon clearly illustrating the principles of the radiation-protective enclosure. Moreover, in the drawings, like reference numerals designate corresponding parts throughout the several views.

FIG. 1 is an isometric view of a radiation-protective enclosure according to an exemplary embodiment of the present invention.

FIG. 2 is an isometric view of a front cover of the radiation-protective enclosure of FIG. 1.

FIG. 3 is a section view of FIG. 2.

FIG. 4 is a partial enlarged view of FIG. 2.

FIG. 5 is a schematic, section view of a cellular phone in use comprising the radiation-protective enclosure of FIG. 1.

FIG. 6 is a partial enlarged view of the front cover of the radiation-protective enclosure according to a second embodiment of the present invention.

FIG. 7 is a partial enlarged view of the front cover of the radiation-protective enclosure according to an third embodiment of the present invention.

### DETAILED DESCRIPTION OF THE EMBODIMENT

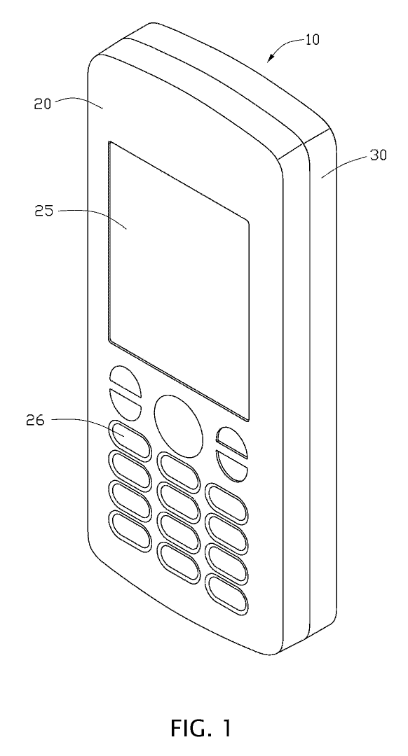

Referring to FIG. 1, a radiation-protective enclosure for a cellular phone according to an exemplary embodiment of the present invention is disclosed. The enclosure 10 includes a front cover 20 and a back cover 30.

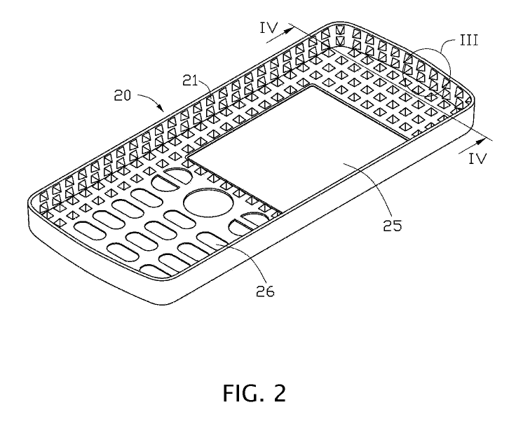

Referring to FIG. 2, the front cover 20 defines a window 25 and a plurality of keypad holes 26.

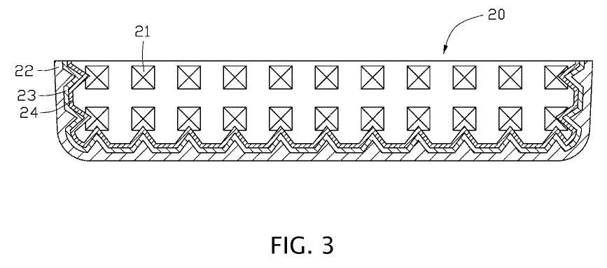

Referring to FIG. 3, the front cover 20 includes a substrate 22, an adhesion layer 23 on an inner surface of the substrate 22, and a reflection layer 24 on the adhesion layer 23. The adhesion layer 23 and the reflection layer 24 are very thin (e.g., about a fraction of a millimeter thick). To clearly distinguish different layers of the front cover 20, the thicknesses of the adhesion layer 23 and the reflection layer 24 shown are not to scale.

The substrate 22 can be made up of plastic, stainless steel, magnesium-aluminum alloy, etc. The adhesion layer 23 is made up of metal oxide. The reflection layer 24 is made up of metals that reflect radiation effectively, for example, aluminium, copper, etc. In other embodiment, the adhesion layer 23 can be omitted.

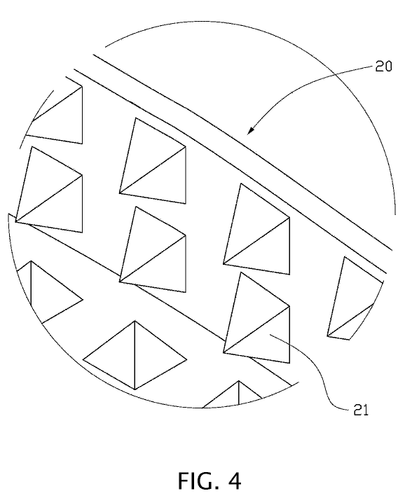

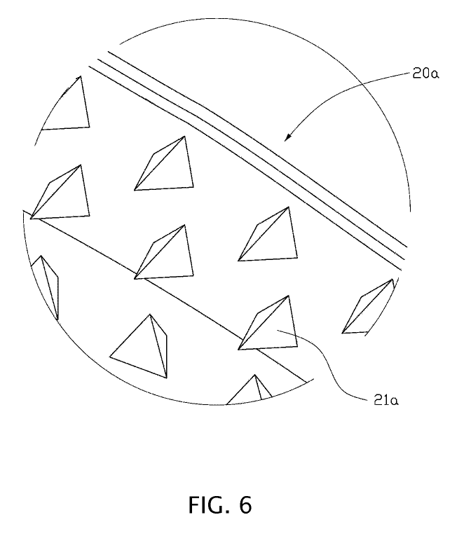

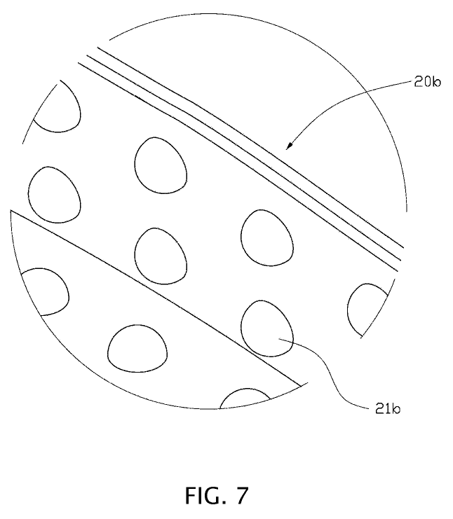

The substrate 22 has a plurality of micro-protrusions. Because the adhesion layer 23 and the reflection layer 24 are formed on the substrate 22 by spraying, the surface of the reflection layer 24 is thus formed with micro-protrusions 21. Referring to FIGS. 4, 6, and 7, the micro-protrusions 21 are square pyramid shaped, triangular pyramid shaped, or dome shaped, etc. The surface of the reflection layer 24 is rugged because of the micro-protrusions 21.

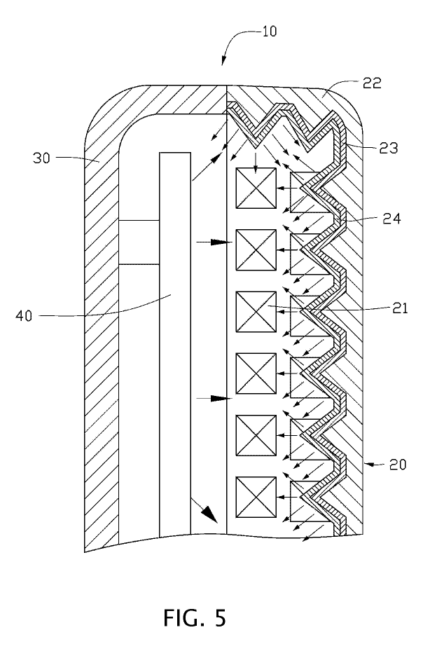

Typically, RF circuits including antennas, such as antenna 40 (shown in FIG. 5) is a source of RF radiation. When the cellular phone, as that shown in FIG. 5, is equipped with the radiation protective enclosure 10, the RF radiation from the RF circuit and antenna 40 is diffusely reflected by the rugged surface of the reflection layer 24. That is, only part of the RF radiation reflects back to the RF circuit. Thus, the interference to the RF circuit is reduced.

Because the front cover 20 faces the user during use, only the front cover 20 of the embodiment of the present invention needs the adhesion layer 23 and the reflection layer 24. However, it should be noted that the back cover 30 could also comprise the adhesion layer 23 and the reflection layer 24.

Moreover, it is to be understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A radiation-protective enclosure for a cellular phone, the radiation-protective enclosure comprising:
a substrate comprising an inner surface; and
a reflection layer formed on the inner surface of the substrate, wherein a surface of the reflection layer is formed with a plurality of micro-protrusions.

2. The radiation-protective enclosure of claim 1, wherein the plurality of micro-protrusions are square pyramid shaped.

3. The radiation-protective enclosure of claim 1, wherein the plurality of micro-protrusions are triangular pyramid shaped.

4. The radiation-protective enclosure of claim 1, wherein the plurality of micro-protrusions are dome shaped.

5. The radiation-protective enclosure of claim 1, wherein material of the reflection layer is copper or aluminium.

6. The radiation-protective enclosure of claim 1, further comprising an adhesion layer between the substrate and the reflection layer.

7. The radiation-protective enclosure of claim 6, wherein material of the adhesion layer is metal oxide.
